(19) United States
(12) Patent Application Publication
(10) Pub. No.: US 2013/0240887 A1
(43) Pub. Date: Sep. 19, 2013

(54) ARRAY SUBSTRATE AND RELEVANT DISPLAY PANEL

(71) Applicant: Yewen Wang, Shenzhen (CN)

(72) Inventor: Yewen Wang, Shenzhen (CN)

(73) Assignee: SHENZHEN CHINA STAR OPTOELECTRONICS TECHNOLOGY CO LTD, Shenzhen (CN)

(21) Appl. No.: 13/502,131

(22) PCT Filed: Mar. 14, 2012
(86) PCT No.: PCT/CN12/72317

§ 371 Date: Apr. 14, 2012

(30) Foreign Application Priority Data
Mar. 13, 2012 (CN) 201210065288.1

(51) Int. Cl. H01L 27/15

(52) U.S. Cl. 257/59; 257/E27.121

(57) ABSTRACT

Disclosed are an array substrate and a relevant display panel. The array substrate has a display area and a peripheral circuit area outside the display area. The array substrate comprises a pixel array and a peripheral circuit. The pixel array comprises thin film transistors and pixel electrodes. The pixel electrodes are graphene thin films. The array substrate and the relevant display panel according to the present invention have low manufacture cost.

### BACKGROUND OF THE INVENTION

1. Field of the Invention

The present invention generally relates to a liquid crystal display field, and more particularly to a liquid crystal substrate and a relevant display panel.

2. Description of Prior Art

With development of technology, kinds of electronic products have become an important portion of human beings' lives. LCD (Liquid crystal display) panel is the main component of the multimedia electronic product. The present TFT-LCD panel provides advantages of power saving, no radiation, small size, lower power consumption, less occupation space, flat square, high resolution, stable image quality and etc. Accordingly, it has been replaced the traditional CRT display (cathode ray tube display) and therefore is widely applied in display panels of the electronic products, such as cell phones, screens, digital televisions, laptop computers and etc.

Along with the rapid development of skills related with liquid display panels. Improvement of the display quality and manufacture cost descend are major priorities of this industry. The display panel generally comprises a CF (color filter) substrate, a TFT array substrate and a liquid crystal layer positioned between the CF substrate and the TFT array substrate. Generally, transparent electrode layers are arranged both at the CF substrate and the TFT array substrate. The material of the transparent electrode layers are generally ITO (Indium Tin Oxides) as an illustration. However, Indium in the ITO is expensive, fragile and lacking of flexibility. Moreover, as wet etching is utilized for fabricating the ITO transparent electrode layers, the etching solvent, the photoresister for protection and the stripper for removing the photoresister are all fundamentally required. The manufacture processes are complicated and deposition in vacuum, annealing are also essential. The manufacture cost is high.

Consequently, there is a need to provide an array substrate and a relevant display panel for solving the existing issues in prior arts.

### SUMMARY OF THE INVENTION

An objective of the present invention embodiments is to provide a array substrate having low manufacture cost to solve the technical issues of high manufacture cost of the array substrate and the relevant display panel according prior art.

The present invention relates to an array substrate, having a display area and a peripheral circuit area outside the display area. The array substrate comprises: a pixel array, positioned in the display area, comprising thin film transistors and pixel electrodes; and a peripheral circuit, positioned in the peripheral circuit area and electrically coupled to the pixel array; the pixel electrodes are graphene thin films having a thickness range within 5-15 nanometers; the thin film transistors further comprise source layers, drain layers and active layers connected to the source layers and the drain layers, and the active layers have a thickness range within 50-60 nanometers.

In the array substrate of the present invention, a length of trenches of the active layers is 5-6 micrometers.

The present invention relates to an array substrate, having a display area and a peripheral circuit area outside the display area. The array substrate comprises: a pixel array, positioned in the display area, comprising thin film transistors and pixel electrodes; and a peripheral circuit, positioned in the peripheral circuit area and electrically coupled to the pixel array; the pixel electrodes are graphene thin films.

In the array substrate of the present invention, the graphene thin films have a thickness range within 5-15 nanometers.

In the array substrate of the present invention, the thin film transistors further comprise source layers, drain layers and active layers connected to the source layers and the drain layers, and the active layers have a thickness range within 50-60 nanometers.

In the array substrate of the present invention, a length of trenches of the active layers is 5-6 micrometers.

In the array substrate of the present invention, an interface of the source layer and the active layer is an oblong and an interface of the drain layer and the active layer is also an oblong.

In the array substrate of the present invention, the pixel electrodes are rectangles.

In the array substrate of the present invention, the rectangles have a length range within 30-40 micrometers and a width range within 15-20 micrometers.

In the array substrate of the present invention, the array substrate further comprises a common electrode, and the pixel electrodes and the common electrode form storage capacitors of the array substrate.

The present invention also relates to a display panel comprising an array substrate, which has a display area and a peripheral circuit area outside the display area. The array substrate comprises a pixel array, positioned in the display area, comprising thin film transistors and pixel electrodes; and a peripheral circuit, positioned in the peripheral circuit area and electrically coupled to the pixel array; the pixel electrodes are graphene thin films.

In the array substrate of the present invention, the graphene thin films have a thickness range within 5-15 nanometers.

In the display panel of the present invention, the thin film transistors further comprise source layers, drain layers and active layers connected to the source layers and the drain layers, and the active layers have a thickness range within 50-60 nanometers.

In the display panel of the present invention, a length of trenches of the active layers is 5-6 micrometers.

In the display panel of the present invention, an interface of the source layer and the active layer is an oblong and an interface of the drain layer and the active layer is also an oblong.

In the display panel of the present invention, the pixel electrodes are rectangles.

In the display panel of the present invention, the rectangles have a length range within 30-40 micrometers and a width range within 15-20 micrometers.

In the display panel of the present invention, the array substrate further comprises a common electrode, and the pixel electrodes and the common electrode form storage capacitors of the array substrate.

With the implement of the array substrate and relevant display panel according to the present invention, obtained advantages are described hereafter: the manufacture cost becomes lower and the technical issues of high manufacture cost of the array substrate and the relevant display panel according to prior art can be solved. Moreover, the pixel electrodes made of graphene thin films provide better conductivities and therefore, the ability for leading the static electricity is outstanding for further meeting the high standard requirement of preventing the static electricity in the display panel at the same time.

For a better understanding of the aforementioned content of the present invention, preferable embodiments are illustrated in accordance with the attached figures for further explanation. Obviously, the following figures are embodiments of the present invention. It is easy for a person skilled in the art to derive other embodiments from these figures.

### BRIEF DESCRIPTION OF THE DRAWINGS

FIG. 1 depicts a planar construction diagram of a preferable embodiment according to the array substrate of the present invention;

FIG. 2 depicts a construction diagram of respective functioned layers in a preferable embodiment according to the array substrate of the present invention.

### DETAILED DESCRIPTION OF THE INVENTION

The following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In figures, the elements with similar structures are indicated by the same number.

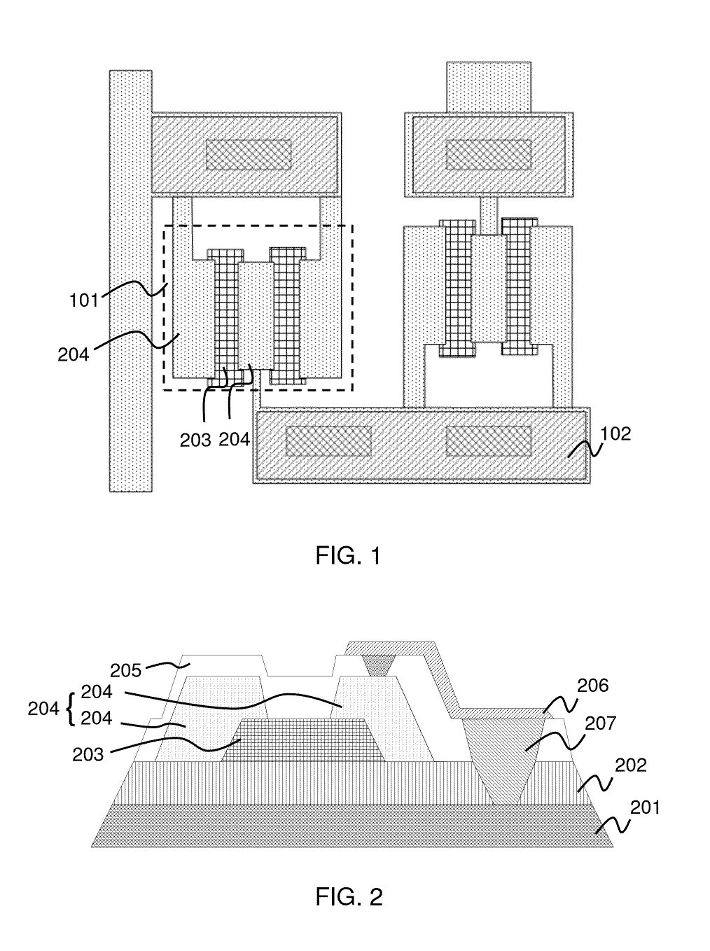

As shown in FIG. 1 and FIG. 2, FIG. 1 depicts a planar construction diagram of a preferable embodiment according to the array substrate of the present invention. FIG. 2 depicts a construction diagram of respective functioned layers in a preferable embodiment according to the array substrate of the present invention. The array substrate shown in FIG. 1 has a display area and a peripheral circuit area outside the display area. The array substrate comprises a pixel array and a peripheral circuit. The pixel array is positioned in the display area and comprises thin film transistors 101 and pixel electrodes 102. The peripheral circuit is positioned in the peripheral circuit area and is electrically coupled to the pixel array. In this embodiment, the pixel electrodes 102 are graphene thin films.

The graphene thin film can be fabricated by chemical vapor deposition, electroanalysis, graphite oxide redox, epitaxial growth, arc discharge and etc. As silicon carbon crystal can be heating up to 1100° C. in vacuum, silicon atoms around the surface of the silicon carbon crystal are evaporated, and the remained carbon atoms are reunited thereby. The graphene thin film can be fabricated, either. The densities, the conductivities and the luminousnesses are completely different for the graphene thin films fabricated by different methods. Furthermore, the adhesive attractions and the dimensions of the aforesaid graphene thin films are also different. By being verified with the experiments, the graphene thin film having a thickness range within 5-15 nanometers provides the better luminousness and the greater conductivity. (As the thickness of the graphene thin film is 10 nanometers, the luminousness is 71% and the conductivity is 550 Siemens/Centimeter.) When the thickness becomes smaller, the graphene thin film gets fragile; when the thickness becomes larger, the luminousness may obviously descend. Moreover, the chemical properties of the graphene thin film is very stable, even contact with the liquid crystal occurs, there is no pollution to the liquid crystal.

Furthermore, the thin film transistor 101 of the array substrate according to the present invention comprises a source layer 2041, a drain layer 2042 and an active layer 203 connected to the source layer 2041 and the drain layer 2042. The active layer 203 has a thickness range within 50-60 nanometers. A length of trench of the active layer 203 is 5-6 micrometers. As shown FIG. 2, a first metal layer 201 preferably comprises an aluminum layer and a first molybdenum layer; the insulating layer 202 preferably comprises a silicon nitride layer; the active layer 203 preferably comprises an amorphous silicon layer; a second metal layer 204 (i.e. the source layer 2041 and the drain layer 2042) preferably comprises a first molybdenum layer, the aluminum layer and a second molybdenum layer; a second insulating layer 205 preferably comprises a silicon nitride layer; a transparent electrode layer 206 (a pixel electrode 102 formed by a lithographic process), in this embodiment, the transparent electrode layer can be a graphene thin film. The contact hole 207 is employed to be filled in with material for transmitting signals among the respective functioned layers. The material also can be grapheme for an illustration. The respective functioned layers shown in FIG. 2 are merely illustrated for description of the present invention but not are drawn in real proportion. Therefore, the proportion in figure cannot be limitation to the present invention.

Moreover, as shown in FIG. 1, an interface of the source layer 2041 and the active layer 203 is an oblong. An interface of the drain layer 2042 and the active layer 203 is also an oblong; the pixel electrode 102 is a rectangle; a length range of the foregoing rectangle is within 30-40 micrometers and a width range of the foregoing rectangle is within 15-20 micrometers. Furthermore, the array substrate of the present invention further comprises a common electrode (not shown). The pixel electrodes 102 and the common electrode form storage capacitors of the array substrate for remaining the driving voltage to the pixel electrode 102.

The graphene thin films of the array substrate according to the present invention can be fabricated without an annealing process and therefore lower manufacture cost can be achieved. Meanwhile, the thickness of the active layer 203 and the trench length of the active layer 203 are arranged to improve the conductivity of the array substrate; with the interface appearance of the source layer 2041 and the active layer 203 and the interface appearance of the drain layer 2042 and the active layer 203 can be employed to guarantee the effective contacts between the source layer 2041 and the active layer 203, and the drain layer 2042 and the active layer 203 respectively. Therefore, the conductivity of the array substrate can be promoted in advance. The appearance and size arrangement of the pixel electrode 102 can be employed for being better functioning and easily realizing the fabrication of the pixel electrode 102 by the grapheme material (Overlarge pixel electrode can cause an easily fragile graphene thin film).

The present invention also relates to a display panel, comprising a CF substrate, the array substrate and a liquid crystal layer. The array substrate has a display area and a peripheral circuit area outside the display area. The array substrate comprises a pixel array and a peripheral circuit. The pixel array is positioned in the display area and comprises thin film transistors 101 and pixel electrodes 102. The peripheral circuit is positioned in the peripheral circuit area and is electrically coupled to the pixel array. The pixel electrodes are graphene thin films have a thickness range within 5-15 nanometers; the thin film transistors further comprise source layers, drain layers and active layers connected to the source layers and the drain layers, and the active layers have a thickness range within 50-60 nanometers; a length of trenches of the active layers is 5-6 micrometer. The functional principle and the beneficial effects of the display panel according to the present invention are the same or similar as the described embodiments of the array substrate as aforementioned. Please refer to the aforementioned embodiments of the array substrate.

With an graphene thin film with specific thickness employed as pixel electrode for the array substrate and the relevant display panel according to the present invention, the manufacture costs of the entire array substrate and the relevant display panel can be significantly diminished. Moreover, the great conductivity of the graphene thin film can guarantee the conductivity of the array substrate. Furthermore, the arrangements for the thickness of the active layer, the trench length of the active layer, the interface appearance of the source layer and the active layer, the interface appearance of the drain layer and the active layer and the appearance of the pixel electrode can be employed for guaranteeing the conductivity of the array substrate. Outstandingly, the technical issues of high manufacture cost and the lousy ability for leading the static electricity of the array substrate and relevant display panel according to prior art can be solved.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. An array substrate, having a display area and a peripheral circuit area outside the display area, wherein the array substrate comprises:
a pixel array, positioned in the display area, comprising thin film transistors and pixel electrodes; and
a peripheral circuit, positioned in the peripheral circuit area and electrically coupled to the pixel array;
the pixel electrodes are graphene thin films having a thickness range within 5-15 nanometers;
the thin film transistors further comprise source layers, drain layers and active layers connected to the source layers and the drain layers, and the active layers have a thickness range within 50-60 nanometers.

2. The array substrate according to claim 1, wherein a length of trenches of the active layers is 5-6 micrometers.

3. An array substrate, having a display area and a peripheral circuit area outside the display area, wherein the array substrate comprises:
a pixel array, positioned in the display area, comprising thin film transistors and pixel electrodes; and
a peripheral circuit, positioned in the peripheral circuit area and electrically coupled to the pixel array;
the pixel electrodes are graphene thin films.

4. The array substrate according to one of claims 3, wherein the graphene thin films have a thickness range within 5-15 nanometers.

5. The array substrate according to claim 3, wherein the thin film transistors further comprise source layers, drain layers and active layers connected to the source layers and the drain layers, and the active layers have a thickness range within 50-60 nanometers.

6. The array substrate according to claim 5, wherein a length of trenches of the active layers is 5-6 micrometers.

7. The array substrate according to claim 5, wherein an interface of the source layer and the active layer is an oblong and an interface of the drain layer and the active layer is also an oblong.

8. The array substrate according to claim 3, wherein the pixel electrodes are rectangles.

9. The array substrate according to claim 8, wherein the rectangles have a length range within 30-40 micrometers and a width range within 15-20 micrometers.

10. The array substrate according to claim 3, wherein the array substrate further comprises a common electrode, and the pixel electrodes and the common electrode form storage capacitors of the array substrate.

11. A display panel, comprising an array substrate, which has a display area and a peripheral circuit area outside the display area, the array substrate comprising:
a pixel array, positioned in the display area, comprising thin film transistors and pixel electrodes; and
a peripheral circuit, positioned in the peripheral circuit area and electrically coupled to the pixel array;
the pixel electrodes are graphene thin films.

12. The display panel according to claim 11, wherein the graphene thin films have a thickness range within 5-15 nanometers.

13. The display panel according to one of claims 11, wherein the thin film transistors further comprise source layers, drain layers and active layers connected to the source layers and the drain layers, and the active layers have a thickness range within 50-60 nanometers.

14. The display panel according to claim 13, wherein a length of trenches of the active layers is 5-6 micrometers.

15. The display panel according to claim 13, wherein an interface of the source layer and the active layer is an oblong and an interface of the drain layer and the active layer is also an oblong.

16. The display panel according to claim 11, wherein the pixel electrodes are rectangles.

17. The display panel according to claim 16, wherein the rectangles have a length range within 30-40 micrometers and a width range within 15-20 micrometers.

18. The display panel according to claim 11, wherein the array substrate further comprises a common electrode, and the pixel electrodes and the common electrode form storage capacitors of the array substrate.
